(19) United States
(12) Patent Application Publication
(10) Pub. No.: US 2021/0335816 A1
(43) Pub. Date: Oct. 28, 2021

(54) NONVOLATILE SEMICONDUCTOR MEMORY DEVICE AND METHOD FOR MANUFACTURING SAME

(71) Applicant: Toshiba Memory Corporation, Tokyo (JP)

(72) Inventors: Akira TAKASHIMA, Kuwana (JP); Kenichiro TORATAI, Kuwana (JP); Masayuki TANAKA, Yokkaichi (JP)

(73) Assignee: Toshiba Memory Corporation, Tokyo (JP)

(21) Appl. No.: 17/366,537

(22) Filed: Jul. 2, 2021

Related U.S. Application Data
(63) Continuation of application No. 15/456,033, filed on Mar. 10, 2017, now abandoned.

(30) Foreign Application Priority Data
Mar. 11, 2016 (JP) 2016-048786

(51) Int. Cl. H01L 27/11582; H01L 27/1157; H01L 27/11568

(52) U.S. Cl. CPC H01L 27/11582; H01L 27/11568; H01L 27/1157

(57) ABSTRACT

According to one embodiment, a nonvolatile semiconductor memory device includes a semiconductor layer, a first electrode, first to third layers, and nitride portions of nitride molecules. The first layer is provided between the semiconductor layer and the first electrode. The second layer is provided between the first layer and the first electrode. The second energy of a conduction band edge of the second layer is lower than a first energy of a conduction band edge of the first layer. The second layer includes a first region and a second region. The first region is provided between the first layer and the second region. The third layer is provided between the second layer and the first electrode. The third energy of a conduction band edge of the third layer is higher than the second energy.

### CROSS-REFERENCE TO RELATED APPLICATIONS

This application is based upon and claims the benefit of priority from Japanese Patent Application No 2016-048788, filed on Mar. 11, 2016; the entire contents of which are incorporated herein by reference.

### FIELD

Embodiments described herein relate generally to a nonvolatile semiconductor memory device and method for manufacturing the same.

### BACKGROUND

It is desirable to increase the bit density of a nonvolatile semiconductor memory device.

### BRIEF DESCRIPTION OF THE DRAWINGS

FIG. 1A to FIG. 1C are schematic views illustrating a nonvolatile semiconductor memory device according to a first embodiment;

FIG. 2A to FIG. 2C are schematic views illustrating a nonvolatile semiconductor memory device according to a second embodiment;

FIG. 3A and FIG. 3B are schematic views illustrating a nonvolatile semiconductor memory device according to a third embodiment;

FIG. 4A and FIG. 4B are schematic cross-sectional views illustrating a nonvolatile semiconductor memory device according to the fourth embodiment;

FIG. 5A to FIG. 5D are schematic cross-sectional views in order of the processes, illustrating the method for manufacturing the nonvolatile semiconductor memory device according to the fourth embodiment;

FIG. 6A to FIG. 6D are schematic cross-sectional views in order of the processes, illustrating another method for manufacturing the nonvolatile semiconductor memory device according to the fourth embodiment;

FIG. 7A and FIG. 7B are schematic cross-sectional views illustrating another nonvolatile semiconductor memory device according to the fourth embodiment;

FIG. 8A to FIG. 8D are schematic cross-sectional views in order of the processes, illustrating the method for manufacturing the other nonvolatile semiconductor memory device according to the fourth embodiment;

FIG. 9A to FIG. 9D are schematic cross-sectional views in order of the processes, illustrating another method for manufacturing the nonvolatile semiconductor memory device according to the fourth embodiment;

FIG. 10A and FIG. 10B are schematic cross-sectional views illustrating another nonvolatile semiconductor memory device according to the fourth embodiment;

FIG. 11A to FIG. 11D are schematic cross-sectional views in order of the processes, illustrating the method for manufacturing the other nonvolatile semiconductor memory device according to the fourth embodiment;

FIG. 12A to FIG. 12D are schematic cross-sectional views in order of the processes, illustrating another method for manufacturing the nonvolatile semiconductor memory device according to the fourth embodiment;

FIG. 13 is a schematic perspective view illustrating the nonvolatile semiconductor memory device according to the fourth embodiment; and

FIG. 14A to FIG. 14C are schematic cross-sectional views illustrating nonvolatile semiconductor memory devices according to the fourth embodiment.

### DETAILED DESCRIPTION

According to one embodiment, a nonvolatile semiconductor memory device includes a semiconductor layer, a first electrode, a first layer, a second layer, a third layer, and a plurality of nitride portions of nitride molecules. The first layer is provided between the semiconductor layer and the first electrode. The second layer is provided between the first layer and the first electrode. The second energy of a conduction band edge of the second layer is lower than a first energy of a conduction band edge of the first layer. The second layer includes a first region and a second region. The first region is provided between the first layer and the second region. The third layer is provided between the second layer and the first electrode. The third energy of a conduction band edge of the third layer is higher than the second energy. The plurality of nitride portions are provided at one of between the first region and the second region, between the first layer and the second layer, or between the second layer and the third layer. The first layer is a tunneling insulating layer. The second layer is a charge storage layer. The third layer is a blocking insulating layer. The nitride molecule includes at least one of TiN, ZrN, HfN, VN, NbN, TaN, CrN, MoN, WN, BN, AlN, GaN, or InN. A length in a first direction of the plurality of nitride portions is not more than a maximum value of a size of the nitride molecule. The first direction is from the semiconductor layer toward the first electrode.

According to another embodiment, a nonvolatile semiconductor memory device includes a semiconductor layer, a first electrode, a first layer, a second layer, a third layer, and a plurality of nitride portions of nitride molecules. The first layer is provided between the semiconductor layer and the first electrode. The second layer is provided between the first layer and the first electrode. The second energy of a conduction band edge of the second layer is lower than a first energy of a conduction band edge of the first layer. The second layer includes a first region and a second region. The first region is provided between the first layer and the second region. The third layer is provided between the second layer and the first electrode. The third energy of a conduction band edge of the third layer is higher than the second energy. The plurality of nitride portions are provided at one of between the first region and the second region, between the first layer and the second layer, or between the second layer and the third layer. The nitride molecule includes nitrogen and a first element of one of Group 4, Group 5, Group 6, or Group 13. A density of the plurality of nitride portions in a surface crossing the first direction is not less than 1×10¹³ cm⁻² and not more than 1×10¹⁵ cm⁻². The first direction is from the semiconductor layer toward the first electrode.

According to another embodiment, a method for manufacturing a nonvolatile semiconductor memory device is provided. The device includes a semiconductor layer, a first electrode, a first layer, a second layer, and a third layer. The first layer is provided between the semiconductor layer and the first electrode. The second layer is provided between the first layer and the first electrode. A second energy of a conduction band edge of the second layer is lower than a first energy of a conduction band edge of the first layer. The third layer is provided between the second layer and the first electrode. A third energy of a conduction band edge of the third layer is higher than the second energy. The method includes forming a plurality of nitride portions of nitride molecules at one of between one portion of the second layer and one other portion of the second layer, between the first region and the second region, between the first layer and the second layer, or between the second layer and the third layer. The nitride molecule includes nitrogen and a first element of one of Group 4, Group 5, Group 6, or Group 13. A length in a first direction of the plurality of nitride portions is not more than a maximum value of a size of the nitride molecule. The first direction is from the semiconductor layer toward the first electrode.

### First Embodiment

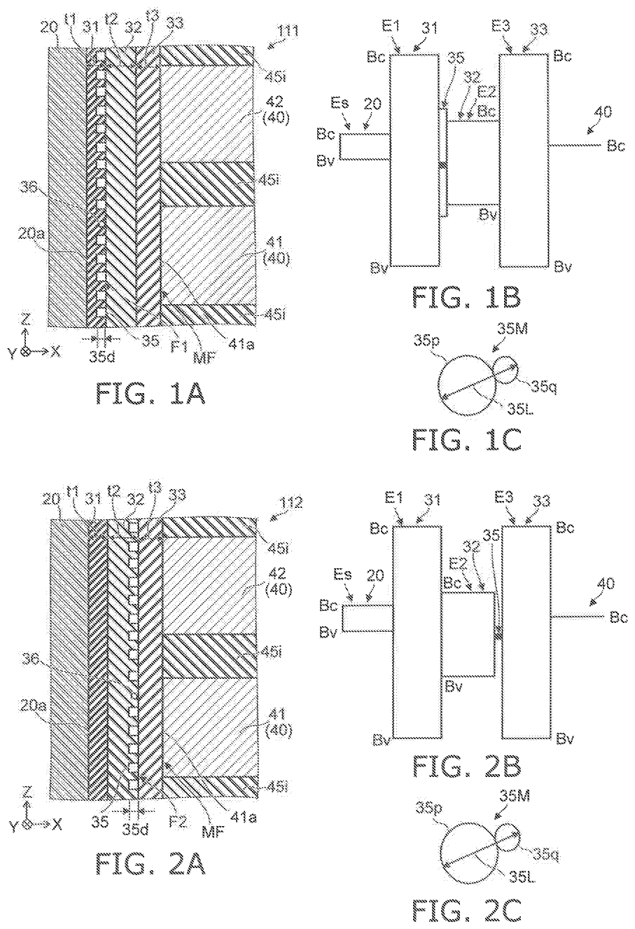

FIG. 1A to FIG. 1C are schematic views illustrating a nonvolatile semiconductor memory device according to a first embodiment.

FIG. 1A is a cross-sectional view. FIG. 1B is an energy band diagram. FIG. 1C is a schematic view showing a molecule included in the nonvolatile semiconductor memory device.

As shown in FIG. 1A, the nonvolatile semiconductor memory device 111 according to the embodiment includes a semiconductor layer 20, a first electrode 41, a first layer 31, a second layer 32, a third layer 33, and multiple nitride portions 35.

The first layer 31 is provided between the semiconductor layer 20 and the first electrode 41. The second layer 32 is provided between the first layer 31 and the first electrode 41. The third layer 33 is provided between the second layer 32 and the first electrode 41.

In the example, the multiple nitride portions 35 are provided between the first layer 31 and the second layer 32. As described below, the multiple nitride portions 35 may be provided between the second layer 32 and the third layer 33 or may be provided inside the second layer 32.

The multiple nitride portions 35 are nitride molecules. The nitride molecules include nitrogen and an element (a first element) of one of Group 4 (Group IVB), Group 5 (Group VB), Group 6 (Group VIE), or Group 13 (Group IIIA).

A direction from the semiconductor layer 20 toward the first electrode 41 is taken as a first direction. The first direction is taken as an X-axis direction. One axis perpendicular to the X-axis direction is taken as a Z-axis direction. A direction perpendicular to the X-axis direction and the Z-axis direction is taken as a Y-axis direction. As described below, the semiconductor layer 20 may have a pillar configuration; in such a case, the direction from the semiconductor layer 20 toward the first electrode 41 corresponds to any direction crossing the extension direction of the pillar.

The semiconductor layer 20 has a surface (a first surface 20a) opposing the first layer 31. For example, the multiple nitride portions 35 are arranged along the first surface 20a of the semiconductor layer 20. For example, the multiple nitride portions 35 are arranged in a surface parallel to the first surface 20a of the semiconductor layer 20.

The first electrode 41 has a surface (a second surface 41a) opposing the third layer 33. For example, the multiple nitride portions 35 are arranged along the second surface 41a of the first electrode 41. For example, the multiple nitride portions 35 are arranged in a surface parallel to the second surface 41a of the first electrode 41.

For example, the multiple nitride portions 35 may be arranged along a surface perpendicular to the first direction (the X-axis direction).

An example of conduction band edges Bc and valence band edges Bv is shown in FIG. 1B. In the specification, the energy of the conduction band edge of silicon is used as the reference for the band alignment, the conduction band barrier height, and the valence band barrier height.

For example, a first energy E1 of the conduction band edge Bc of the first layer 31 is higher than an energy Es of the conduction band edge Bc of the semiconductor layer 20. The first layer 31 includes, for example, a material that is insulative. For example, the first layer 31 corresponds to a tunneling insulating layer.

For example, a second energy E2 of the conduction band edge Bc of the second layer 32 is higher than the energy Es of the conduction band edge Bc of the semiconductor layer 20. The second layer 32 includes, for example, a material that is insulative.

For example, a third energy E3 of the conduction band edge Bc of the third layer 33 is higher than the energy Es of the conduction band edge Bc of the semiconductor layer 20. The third layer 33 includes, for example, a material that is insulative. For example, the third layer 33 corresponds to a blocking insulating film.

The second energy E2 of the conduction band edge Bc of the second layer 32 is lower than the first energy E1 of the conduction band edge Bc of the first layer 31. The second energy E2 of the conduction band edge Bc of the second layer 32 is lower than the third energy E3 of the conduction band edge Bc of the third layer 33. In other words, the third energy E3 of the third layer 33 is higher than the second energy E2. For example, the second layer 32 functions as a charge storage layer.

For example, the first layer 31 includes silicon oxide. For example, the second layer 32 includes silicon nitride. For example, the third layer 33 includes silicon oxide.

For example, the potential (the voltage) of the semiconductor layer 20 is used as a reference in the nonvolatile semiconductor memory device 111. For example, when a positive voltage is applied to the first electrode 41, charge (electrons) passes through the first layer 31 (the tunneling insulating layer) from the semiconductor layer 20 and is injected into the second layer 32 (the charge storage layer). The movement of the injected charge into the first electrode 41 is suppressed by the third layer 33 (the blocking insulating film). The charge that is injected into the second layer 32 is trapped in the second layer 32 and is stored in the second layer 32. The threshold of the current flowing in the semiconductor layer 20 changes due to the existence or absence (the amount) of the charge inside the second layer 32. A first state is formed by this operation (e.g., a program operation). By applying a voltage of the reverse polarity of the voltage recited above between the semiconductor layer 20 and the first electrode 41, the charge that is stored in the second layer 32 moves into the semiconductor layer 20. A second state is formed by this operation (e.g., an erasing operation). A read operation of the stored state is performed by sensing the thresholds of the first state and the second state.

The first to third layers 31 to 33 and the multiple nitride portions 35 are included in a memory film MF. The semiconductor layer 20, the first electrode 41, and the memory film MF correspond to one memory cell (a first memory cell). The semiconductor layer 20 corresponds to a channel body.

In the embodiment, the nitride molecules of the multiple nitride portions 35 include, for example, at least one of BN, AlN, GaN, or InN.

As shown in FIG. 1C, the nitride molecule 35M includes a first element 35p (a first atom) and a nitrogen atom 35q. The first element 35p is an element of one of Group 4 (Group IVB), Group 5 (Group VB), Group 6 (Group VIB), or Group 13 (Group IIIA). The first element 35p is, for example, one of boron (B), aluminum (Al), gallium (Ga), or indium (In).

The configuration of the nitride molecule 35M is not a sphere. As shown in FIG. 1C, for example, a maximum value 35L of the size of the nitride molecule 35M corresponds to the length of the nitride molecule 35M along a direction connecting the first element 35p and the nitrogen atom 35q.

A length 35d (the thickness referring to FIG. 1A) of the multiple nitride portions 35 in the first direction (the direction from the semiconductor layer 20 toward the first electrode 41) is not more than the maximum value 35L of the size of the nitride molecule 35M.

For example, the multiple nitride portions 35 are dispersed in the state of single molecules of the nitride molecules 35M. The thickness of the region where the multiple nitride portions 35 are provided substantially is not more than about the maximum value 35L of the size of the nitride molecule 35M.

Due to the application of the electric field (the voltage) in the nonvolatile semiconductor memory device 111, the charge moves into the second layer 32 (the charge storage layer) after passing through the first layer 31 (the tunneling insulating layer) from the semiconductor layer 20. For example, for the charge that moves in the second layer 32, the probability of passing through toward the first layer 31 is reduced by the barrier height of the multiple nitride portions 35. Thereby, for example, the probability of the charge being trapped in the second layer 32 increases. Because the storage efficiency of the charge increases, for example, the range of the possible threshold voltages is enlarged.

For example, the trapping efficiency of the trap sites of the second layer 32 can be increased while forming trap sites in an interface F1 between the first layer 31 and the second layer 32. Thereby, the range of the possible threshold voltages can be enlarged.

For example, there is a first reference example in which a layer of a nitride (e.g., having a thickness of 3 nm) is provided between the tunneling insulating layer and the charge storage layer. In the first reference example, the layer of the nitride includes a crystal structure body such as metal dots. The size of the crystal structure body is markedly larger than the size of the molecules of the nitride. In the first reference example, the distance between the nitride and the semiconductor layer fluctuates within the thickness (e.g., 3 nm) of the layer of the nitride. The threshold fluctuates if the distance between the metal oxide and the semiconductor layer fluctuates. Therefore, in the first reference example, the stability of the threshold is insufficient.

Conversely, in the embodiment, the length 35d (the thickness) of the multiple nitride portions 35 is not more than the maximum value 35L of the size of the nitride molecule 35M. The multiple nitride portions 35 are dispersed in the state of single molecules of the nitride molecules 35M. The distance between the semiconductor layer 20 and the nitride portions 35 is substantially constant. Therefore, the fluctuation of the threshold is small.

On the other hand, there is a second reference example in which particles of a metal are provided inside the memory film MF (between the silicon oxide film and the silicon nitride film or inside the silicon nitride film). The trappability of the charge is low in the second reference example. Further, in the second reference example, uncontrolled bonds form easily due to incomplete oxidization of the metal. Therefore, for example, the control of the positions of the trap sites based on the metal particles is difficult. For example, the multiple trap sites easily approach each other too much. Therefore, the data retention characteristics degrade.

Conversely, in the embodiment, the multiple nitride portions 35 of the nitride molecules 35M are provided. In the case where the nitride molecules 35M are BN, AlN, GaN, and InN, for example, traps that have different trapping cross-sectional areas are formed. Thereby, the trapping efficiency can be increased. Because the nitride molecules 35M are used, the uncontrolled formation of the metal oxide, etc., is suppressed. The multiple nitride portions 35 (the nitride molecules 35M) are disposed to be dispersed (in a two-dimensional configuration) along a surface (in the example, the interface F1 between the first layer 31 and the second layer 32). Discrete traps are formed by the multiple nitride portions 35 at the desired position in the film thickness direction (the first direction). Good data retention characteristics are obtained.

In the embodiment, the density (the surface density) of the multiple nitride portions 35 is, for example, not less than 1×10¹³ cm⁻² and not more than 1×10¹⁵ cm⁻². The density is the density (the surface density) in a surface crossing the first direction (the direction from the semiconductor layer 20 toward the first electrode 41). The surface that crosses the first direction is, for example, a surface perpendicular to the first direction.

For example, if the distance between two nitride molecules 35M is less than 3 nm, the charge that is trapped moves easily to proximal traps by direct tunneling. It is favorable for the distance between the two nitride molecules 35M to be 3 nm or more. Thereby, the direct tunneling can be suppressed; and the hopping of the charge can be suppressed. For example, it is assumed that the multiple nitride molecules 35M are circles having diameters of 3 nm with maximum packing (corresponding to 1.156 times). Further, it is assumed that one nitride molecule 35M is disposed at each of the eight corners of the cube. In such a case, the number of the nitride molecules 35M provided in a 1 cm by 1 cm region is 1 cm×1 cm×1.156×8/(3 nm×3 nm), i.e., about 1.03×10¹⁵ cm⁻².

By setting the density of the multiple nitride portions 35 to be not more than 1×15 cm⁻², for example, the direct tunneling can be suppressed; and good retention characteristics are obtained. By setting the density of the multiple nitride portions 35 to be not less than 1×10¹³ cm⁻², for example, the enlargement of the range of the threshold voltages possible by providing the nitride portions 35 is performed effectively.

In the nonvolatile semiconductor memory device 111, the nitride molecules 35M of the multiple nitride portions 35 may include, for example, at least one of TiN, ZrN, HfN, VN, NbN, TaN, CrN, MoN, or WN. The first element 35p (the first atom) may be, for example, one of titanium (Ti), zirconium (Zr), hafnium (Hf), vanadium (V), niobium (Nb), tantalum (Ta), chrome (Cr), molybdenum (Mo), or tungsten (W).

For example, the work function of Ti is 4.1 eV; and the work function of TiN is 4.6 eV. The trappability of charge by the particles of a metal is lower than the trappability of charge by a nitride. Therefore, for example, the data retention characteristics are insufficient in the second reference example recited above in which the particles of a metal are used.

Conversely, in the embodiment, a high trappability of charge is obtained in the case where the multiple nitride portions 35 are molecules of TiN, ZrN, HfN, VN, NbN, TaN, CrN, MoN, WN, etc. Also, the length 35d (the thickness) in the first direction of the multiple nitride portions 35 is not more than the maximum value 35L of the size of the nitride molecule 35M; and the multiple nitride portions 35 are dispersed in the state of single molecules of the nitride molecules 35M. Thereby, in the embodiment, for example, good data retention characteristics are obtained.

A trap having a deep level is formed in a nitride because the work function is large. Thereby, the charge that is trapped is not de-trapped easily. As a result, for example, the data retention characteristics improve. The difficult de-trapping of the charge also means that the trapped charge is difficult to de-trap in the programming. Thereby, it appears that the programming efficiency increases. For example, because a high electric field is applied in the programming, if the level of the trap is shallow, the trapped charge de-traps due to the high electric field during the program time. Conversely, this is suppressed in the case where the level of the trap is deep. Therefore, it appears that the programming efficiency increases.

Thus, in the embodiment, a stable bond is formed between the first element 35p and the nitrogen atom 35q for the multiple nitride portions 35 of the memory film MF. By using the nitride molecules 35M, for example, the work function is large; and a deep level is obtained. By using the multiple nitride portions 35, the trapping amount of the charge can be increased. The multiple nitride portions 35 of the nitride molecules 35M are arranged along a surface crossing the film thickness direction. Thereby, a stable threshold is obtained. The tolerance range of the programming voltage and the erasing voltage can be enlarged.

For example, stable operations are obtained even if the size of the memory cell is reduced. As a result, for example, the bit density can be increased.

By setting the surface density of the multiple nitride portions 35 to be, for example, not less than 1×10¹³ cm² and not more than 1×10¹⁵ cm⁻², the diffusion in the horizontal direction (a direction crossing the first direction) of the charge can be suppressed. Thereby, good retention is obtained.

A particle 36 of the first element 35p included in the nitride molecules 35M may be further provided in the nonvolatile semiconductor memory device 111 (referring to FIG. 1A). The particle 36 of the first element is provided also in the multiple nitride portions 35. In the example of FIG. 1A, the particle 36 of the first element is provided between the first layer 31 and the second layer 32.

In such a case, the average nitrogen concentration in the region including the multiple nitride portions 35 and the particle 36 of the first element is lower than the nitrogen concentration of the stoichiometric ratio of the nitride molecule 35M. Thus, in this region, nitrogen may be deficient with respect to the stoichiometric ratio. Thereby, for example, a defect level is formed inside the bandgap in this region. For example, in the case of aluminum nitride, the defect level is formed at the central vicinity of the bandgap. The defect level is deep and is in the vicinity of 2.9 eV from the conduction band edge Bc. Thereby, it is extremely difficult for the charge to move at the trap sites that are formed. Thereby, the data retention characteristics can be improved. Further, the range of the possible threshold voltages can be enlarged.

A second electrode 42 and an inter-layer insulating film 45i are provided in the nonvolatile semiconductor memory device 111 as shown in FIG. 1A. Thus, the nonvolatile semiconductor memory device 111 may include multiple electrodes 40. The first electrode 41 and the second electrode 42 are included in the multiple electrodes 40. The second electrode 42 is arranged with the first electrode 41 in the second direction (e.g., the Z-axis direction) crossing the first direction (the X-axis direction). The inter-layer insulating film 45i is provided between the multiple electrodes 40.

The first layer 31 is further provided between the second electrode 42 and the semiconductor layer 20. The second layer 32 is further provided between the second electrode 42 and the first layer 31. The third layer 33 is further provided between the second electrode 42 and the second layer 32.

The semiconductor layer 20, the second electrode 42, and the memory film MF correspond to one other memory cell (a second memory cell). In the second memory cell as well, the fluctuation of the threshold is small; and the range of the possible threshold voltages can be enlarged. For example, the distance between the first electrode 41 and the second electrode 42 can be short. The bit density can be increased.

In the embodiment, a thickness t1 (the length along the first direction referring to FIG. 1A) of the first layer 31 is, for example, not less than 2 nanometers and not more than 8 nanometers. A thickness t2 (the length along the first direction referring to FIG. 1A) of the second layer 32 is, for example, not less than 2 nanometers and not more than 8 nanometers. A thickness t3 (the length along the first direction referring to FIG. 1A) of the third layer 33 is, for example, not less than 3 nanometers and not more than 10 nanometers.

### Second Embodiment

FIG. 2A to FIG. 2C are schematic views illustrating a nonvolatile semiconductor memory device according to a second embodiment.

FIG. 2A is a cross-sectional view. FIG. 2B is an energy band diagram. FIG. 2C is a schematic view showing a molecule included in the nonvolatile semiconductor memory device.

As shown in FIG. 2A, the semiconductor layer 20, the first electrode 41, the first to third layers 31 to 33, and the multiple nitride portions 35 are provided in the nonvolatile semiconductor memory device 112 according to the embodiment as well. The semiconductor layer 20, the first electrode 41, and the first to third layers 31 to 33 are similar to those of the nonvolatile semiconductor memory device 111; and a description is therefore omitted.

The multiple nitride portions 35 of the nonvolatile semiconductor memory device 112 will now be described.

In the nonvolatile semiconductor memory device 112, the multiple nitride portions 35 of the nitride molecules 35M are provided between the second layer 32 and the third layer 33. The multiple nitride portions 35 are provided along an interface F2 between the second layer 32 and the third layer 33. In the example as well, the length 35d (the thickness) in the first direction (the direction from the semiconductor layer 20 toward the first electrode 41) of the multiple nitride portions 35 is not more than the maximum value 35L of the size of the nitride molecule 35M (referring to FIG. 2C). For example, the multiple nitride portions 35 are dispersed in the state of single molecules of the nitride molecules 35M.

For example, the multiple nitride portions 35 are arranged along the first surface 20a of the semiconductor layer 20. For example, the multiple nitride portions 35 are arranged along the second surface 41a of the first electrode 41.

In the nonvolatile semiconductor memory device 112, the nitride molecules 35M of the multiple nitride portions 35 (referring to FIG. 2C) include, for example, at least one of TiN, ZrN, HfN, VN, NbN, TaN, CrN, MoN, or WN.

The first element 35p (the first atom) is, for example, one of titanium (Ti), zirconium (Zr), hafnium (Hf), vanadium (V), niobium (Nb), tantalum (Ta), chrome (Cr), molybdenum (Mo), or tungsten (W).

As shown in FIG. 2B, in the nonvolatile semiconductor memory device 112 as well, the second energy E2 of the conduction band edge Bc of the second layer 32 is lower than the first energy E1 of the conduction band edge Bc of the first layer 31 and lower than the third energy E3 of the conduction band edge Bc of the third layer 33. For example, the first layer 31 includes silicon oxide. For example, the second layer 32 includes silicon nitride. For example, the third layer 33 includes silicon oxide.

Due to the electric field application, the charge passes through the first layer 31 (e.g., the tunneling insulating layer) and the second layer 32 (the charge storage layer) from the semiconductor layer 20 and reaches the nitride portions 35. The nitride portions 35 function as trap sites.

For example, the nitride portions 35 are titanium nitride. The work function of titanium nitride is 4.5 eV. Due to the titanium nitride, a deep level is formed at the central vicinity of the bandgap of the second layer 32 (the charge storage layer, e.g., a silicon nitride film). Thereby, good data retention characteristics are obtained. The range of the possible threshold voltages can be enlarged.

In the nonvolatile semiconductor memory device 112, the trap sites at the interface F2 between the second layer 32 (e.g., the charge storage layer) and the third layer 33 (e.g., the blocking insulating film) can be increased. Further, the trapping efficiency of the trap sites at the interface F2 vicinity can be increased. Thereby, the range of the possible threshold voltages can be enlarged.

For example, the distance between the semiconductor layer 20 and the nitride portions 35 is substantially constant. Therefore, the fluctuation of the threshold is small.

In the embodiment, for example, stable operations are obtained even if the size of the memory cell is reduced. As a result, for example, the bit density can be increased.

In the nonvolatile semiconductor memory device 112, the density of the multiple nitride portions 35 may be not less than 1×10¹³ cm⁻² and not more than 1×10¹⁵ cm⁻², for example, the direct tunneling can be suppressed; and good retention characteristics are obtained. By setting the density of the multiple nitride portions 35 to be not less than 1×10¹³ cm⁻², for example, the enlargement of the range of the possible threshold voltages is performed effectively.

The particle 36 of the first element 35p included in the nitride molecules 35M may be further provided in the nonvolatile semiconductor memory device 112 (referring to FIG. 2A). In the example, the particle 36 of the first element 35p is provided between the second layer 32 and the third layer 33. Thereby, the data retention characteristics can be improved. Further, the range of the possible threshold voltages can be enlarged.

### Third Embodiment

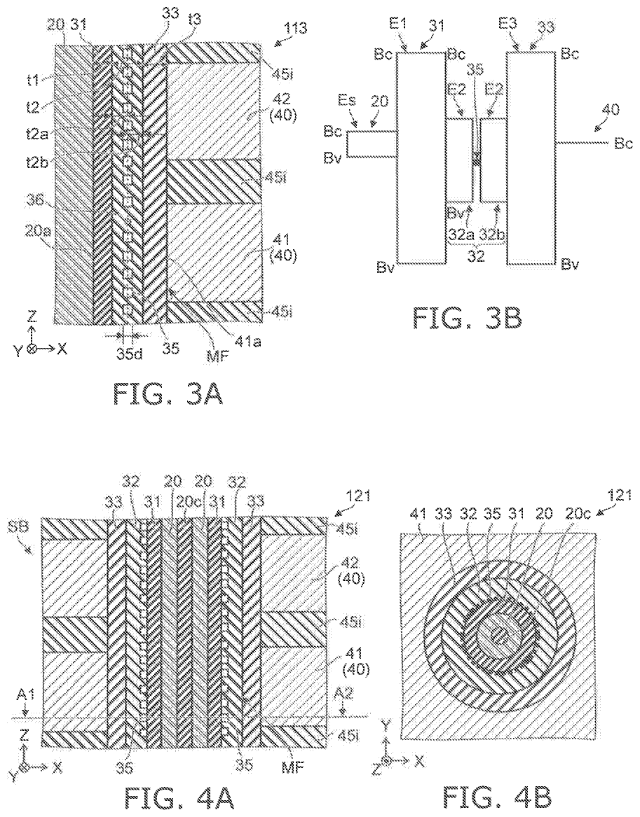

FIG. 3A and FIG. 3B are schematic views illustrating a nonvolatile semiconductor memory device according to a third embodiment.

FIG. 3A is a cross-sectional view. FIG. 3B is an energy band diagram.

As shown in FIG. 3A, the semiconductor layer 20, the first electrode 41, the first to third layers 31 to 33, and the multiple nitride portions 35 are provided in the nonvolatile semiconductor memory device 113 according to the embodiment as well. The semiconductor layer 20, the first electrode 41, the first layer 31, and the third layer 33 are similar to those of the nonvolatile semiconductor memory device 111; and a description is therefore omitted.

The second layer 32 and the multiple nitride portions 35 of the nonvolatile semiconductor memory device 113 will now be described.

The multiple nitride portions 35 of the nitride molecules 35M are provided inside the second layer 32 in the nonvolatile semiconductor memory device 113.

As shown in FIG. 3A, the second layer 32 includes a first region 32a and a second region 32b. The first region 32a is provided between the first layer 31 and the second region 32b. The first region 32a is the region on the first layer 31 side. The second region 32b is the region on the third layer 33 side.

The multiple nitride portions 35 are provided between the first region 32a and the second region 32b.

In the example as well, the length 35d (the thickness) in the first direction (the direction from the semiconductor layer 20 toward the first electrode 41) of the multiple nitride portions 35 is not more than the maximum value 35L of the size of the nitride molecule 35M (similar to FIG. 2C). For example, the multiple nitride portions 35 are dispersed in the state of single molecules of the nitride molecules 35M.

For example, the multiple nitride portions 35 are arranged along the first surface 20a of the semiconductor layer 20. For example, the multiple nitride portions 35 are arranged along the second surface 41a of the first electrode 41.

In the nonvolatile semiconductor memory device 113, the nitride molecules 35M of the multiple nitride portions 35 (similar to FIG. 2C) include, for example, at least one of TiN, ZrN, HfN, VN, NbN, TaN, CrN, MoN, or WN. The first element 35p (the first atom) is, for example, one of titanium (Ti), zirconium (Zr), hafnium (Hf), vanadium (V), niobium (Nb), tantalum (Ta), chrome (Cr), molybdenum (Mo), or tungsten (W).

As shown in FIG. 3B, the second energy E2 of the conduction band edge Bc of the second layer 32 is lower than the first energy E1 of the conduction band edge Bc of the first layer 31 and lower than the third energy E3 of the conduction band edge Bc of the third layer 33 in the nonvolatile semiconductor memory device 113 as well. For example, the first layer 31 includes silicon oxide. For example, the second layer 32 includes silicon nitride. For example, the third layer 33 includes silicon oxide.

Due to the application of the electric field, the charge passes through the first layer 31 (e.g., the tunneling insulating layer) and the first region 32a of the second layer 32 from the semiconductor layer 20 and reaches the multiple nitride portions 35. The multiple nitride portions 35 are used as trap sites. For example, the nitride portions 35 are molecules of tungsten nitride. The work function of tungsten nitride is 4.6 eV. Due to the tungsten nitride, a deep level can be formed at the central vicinity of the bandgap of the second layer 32 (e.g., the silicon nitride). Thereby, good data retention characteristics are obtained. Further, the range of the possible threshold voltages can be enlarged.

For example, discrete trap sites are formed in the first region 32a and the second region 32b of the second layer 32. The trapping efficiency of the trap sites can be increased. Thereby, the range of the possible threshold voltages can be enlarged.

For example, the distance between the semiconductor layer 20 and the nitride portions 35 is substantially constant. Therefore, the fluctuation of the threshold is small.

In the embodiment, for example, stable operations are obtained even if the size of the memory cell is reduced. As a result, for example, the bit density can be increased.

In the nonvolatile semiconductor memory device 113, the density of the multiple nitride portions 35 may be not less than 1×10¹³ cm⁻² and not more than 1×10¹⁵ cm⁻² For example, the direct tunneling can be suppressed; and good retention characteristics are obtained. By setting the density of the multiple nitride portions 35 to be not less than 1×10¹³ cm⁻², for example, the enlargement of the range of the possible threshold voltages is performed effectively.

In the second layer 32 of the nonvolatile semiconductor memory device 113, a thickness t2a of the first region 32a may be substantially the same as a thickness t2b of the second region 32b. For example, the thickness t2a of the first region 32a is not less than 0.5 times and not more than 15 times the thickness t2b of the second region 32b.

In the nonvolatile semiconductor memory device 113, the particle 36 of the first element 35p included in the nitride molecules 35M may be further provided (referring to FIG. 3A). In the example, the particle 36 of the first element is provided between the first region 32a and the second region 32b. Thereby, the data retention characteristics can be improved. Further, the range of the possible threshold voltages can be enlarged.

In the nonvolatile semiconductor memory devices 112 and 113, the nitride molecules of the multiple nitride portions 35 may include, for example, at least one of BN, AlN, GaN, or InN. The nitride molecules 35M include the first element 35p (the first atom) and the nitrogen atom 35q (e.g., referring to FIG. 2C). The first element 35p may be one of boron (B), aluminum (Al), gallium (Ga), or indium (In). In such a case as well, for example, stable operations are obtained even if the size of the memory cell is reduced. As a result, for example, the bit density can be increased.

In the nonvolatile semiconductor memory devices 111 to 113 according to the first to third embodiments recited above, information relating to at least a portion of the state of the multiple nitride portions 35 is obtained by, for example, TEM-EELS (Transmission Electron Microscope-electron energy loss spectroscopy). The information relating to the at least a portion of the state of the multiple nitride portions 35 may be obtained by, for example, SIMS (Secondary Mass Spectrometry). The information relating to the at least a portion of the state of the multiple nitride portions 35 may be obtained by, for example, analysis using a three-dimensional atom probe. For example, LEAP 4000 (CAMECA SAS), etc., can be used as the three-dimensional atom probe.

### Fourth Embodiment

In a fourth embodiment, the semiconductor layer 20 has a pillar configuration.

FIG. 4A and FIG. 4B are schematic cross-sectional views illustrating a nonvolatile semiconductor memory device according to the fourth embodiment.

FIG. 4B is a line A1-A2 cross-sectional view of FIG. 4A.

As shown in FIG. 4A, the semiconductor layer 20, the first electrode 41, the second electrode 42, the inter-layer insulating film 45i, the first to third layers 31 to 33, and the multiple nitride portions 35 are provided in the nonvolatile semiconductor memory device 121 according to the embodiment.

The second electrode 42 is arranged with the first electrode 41 in the second direction (e.g., the Z-axis direction) crossing the first direction (the direction from the semiconductor layer 20 toward the first electrode 41). The inter-layer insulating film 45i is provided between the multiple electrodes 40. The portions of the nonvolatile semiconductor memory device 121 that are different from those of the nonvolatile semiconductor memory device 111 will now be described.

The first electrode 41, the inter-layer insulating film 45i, and the second electrode 42 are included in a stacked body SB. The semiconductor layer 20 extends along the second direction (the Z-axis direction) through the stacked body SB.

A core pillar 20c is provided in the example. The core pillar 20c extends in the Z-axis direction through the stacked body SB. The core pillar 20c is, for example, insulative.

As shown in FIG. 4A and FIG. 4B, the semiconductor layer 20 is provided around the core pillar 20c. For example, the semiconductor layer 20 has a pipe configuration. The first layer 31 is provided around the semiconductor layer 20. The second layer 32 is provided around the first layer 31. The third layer 33 is provided around the second layer 32. The first to third layers 31 to 33 have pipe configurations. The electrodes 40 (the first electrode 41, the second electrode 42, etc.) are provided around the third layer 33.

In the nonvolatile semiconductor memory device 121, the multiple nitride portions 35 of the nitride molecules 35M are provided between the first layer 31 and the second layer 32. In the nonvolatile semiconductor memory device 121 as well, for example, stable operations are obtained even if the size of the memory cell is reduced. As a result, for example, the bit density can be increased.

An example of a method for manufacturing the nonvolatile semiconductor memory device 121 will now be described.

The manufacturing method is a method for manufacturing the nonvolatile semiconductor memory device 121 including the semiconductor layer 20, the first electrode 41, the first layer 31 that is provided between the semiconductor layer 20 and the first electrode 41, the second layer 32 that is provided between the first layer 31 and the first electrode 41, and the third layer 33 that is provided between the second layer 32 and the first electrode 41. As described above, the second energy E2 of the conduction band edge Bc of the second layer 32 is lower than the first energy E1 of the conduction band edge Bc of the first layer 31. The third energy E3 of the conduction band edge Bc of the third layer 33 is higher than the second energy E2. The manufacturing method includes forming the first layer 31, forming the second layer 32, forming the third layer 33, and forming the multiple nitride portions 35.

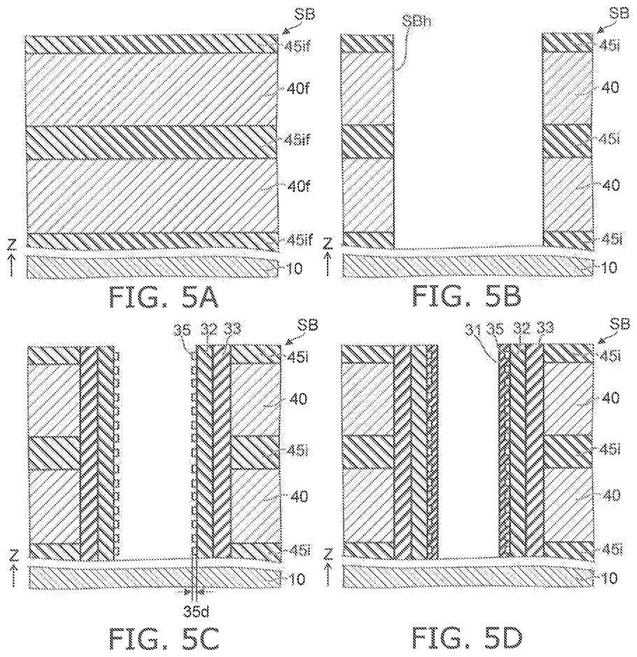

FIG. 5A to FIG. 5D are schematic cross-sectional views in order of the processes, illustrating the method for manufacturing the nonvolatile semiconductor memory device according to the fourth embodiment.

As shown in FIG. 5A, a conductive layer 40f that is used to form the electrode 40, and an insulating layer 45if that is used to form the inter-layer insulating film 45i are stacked alternately on a base body 10. The conductive layer 40f is, for example, tungsten. The insulating layer 45if is, for example, silicon oxide. The stacked body SB is formed. The stacking direction corresponds to the Z-axis direction.

As shown in FIG. 5B, a hole SBh is formed in the stacked body SB. The hole SBh extends in the Z-axis direction.

As shown in FIG. 5C, the third layer 33 is formed on the side wall of the hole SBh; and the second layer 32 is formed on the third layer 33. The multiple nitride portions 35 are formed on the surface of the second layer 32.

To form the multiple nitride portions 35, for example, atomic layer deposition (ALD) is performed using a gas (e.g., titanium chloride, etc.) including the first element 35p and a gas (e.g., ammonia) including the nitrogen atom 35q. For example, the number of cycles of the ALD, the atmosphere (e.g., the pressure of the ammonia gas, etc.) of the ALD, the temperature of the ALD, etc., are controlled. Thereby, the multiple nitride portions 35 of the nitride molecules 35M are formed on the surface of the second layer 32. The length 35d in the first direction (a direction crossing the Z-axis direction and corresponding to a direction from the semiconductor layer 20 toward the first electrode 41) of the multiple nitride portions 35 is not more than the maximum value 35L of the size of the nitride molecule 35M.

As shown in FIG. 5D, the first layer 31 is formed on a portion of the surface of the second layer 32 and on the multiple nitride portions 35.

The nonvolatile semiconductor memory device 121 can be formed by further forming the semiconductor layer 20 on the surface of the first layer 31 and by further forming the core pillar 20c by filling an insulating material into the remaining space.

In the example, the forming of the second layer 32 is implemented after the forming of the third layer 33. Then, the forming of the multiple nitride portions 35 is implemented after the forming of the second layer 32. Then, the forming of the first layer 31 is implemented after the forming of the multiple nitride portions 35.

In the embodiment, the density of the multiple nitride portions 35 in a Surface (a surface having a tubular configuration between the second layer 32 and the third layer 33) crossing the first direction (the Z-axis direction) is, for example, not less than 1×10¹³ cm⁻² and not more than 1×10¹⁵ cm⁻².

Another example of a method for manufacturing the nonvolatile semiconductor memory device 121 will now be described. A replacement method is used in this method.

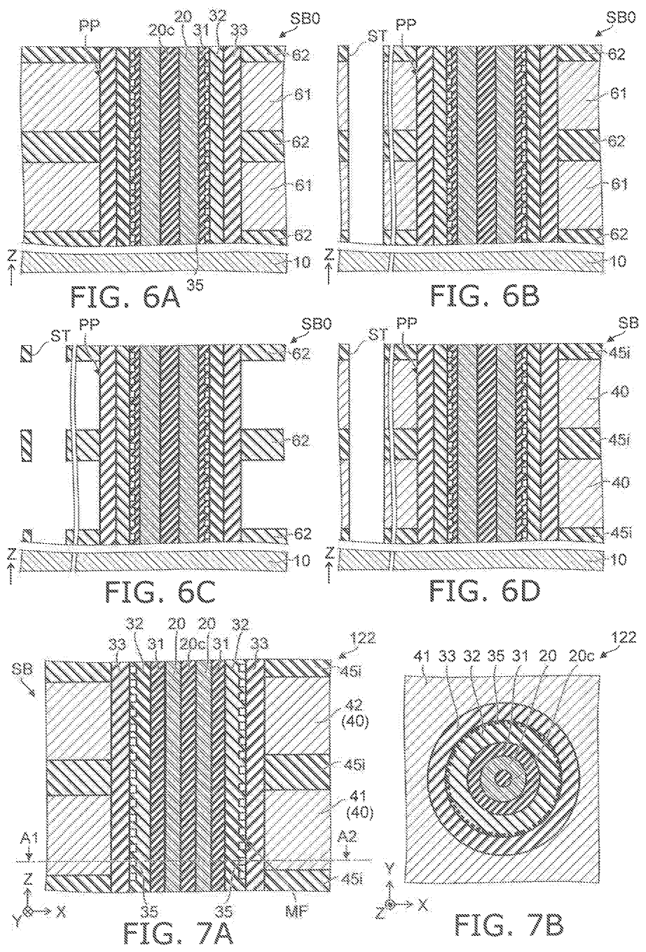

FIG. 6A to FIG. 6D are schematic cross-sectional views in order of the processes, illustrating another method for manufacturing the nonvolatile semiconductor memory device according to the fourth embodiment.

As shown in FIG. 6A, multiple first films 61 and multiple second films 62 are stacked alternately on the base body 10. The first film 61 is, for example, a sacrificial layer. For example, the second film 62 is used to form the inter-layer insulating film 45i. The first film 61 is, for example, a silicon nitride film. The second film 62 is, for example, a silicon oxide film. Thereby, a stacked body SB0 is formed.

Further, a hole is formed in the stacked body SB0; and the third layer 33, the second layer 32, the multiple nitride portions 35, the first layer 31, the semiconductor layer 20, and the core pillar 20c are sequentially formed in the hole. Thereby, a pillar unit PP that includes the third layer 33, the second layer 32, the multiple nitride portions 35, the first layer 31, the semiconductor layer 20, and the core pillar 20c is formed.

As shown in FIG. 6B, a slit ST (that may be a hole) is formed in the stacked body SB0.

As shown in FIG. 6C, the first films 61 are removed via the slit ST.

As shown in FIG. 6D, the electrodes 40 are formed by filling a conductive material into the space formed where the first films 61 were removed. The remaining second films 62 become the inter-layer insulating films 45i.

Thereby, the nonvolatile semiconductor memory device 121 is formed.

Thus, the manufacturing method includes forming the sacrificial layers (the first films 61), removing the sacrificial layers, and forming the first electrode 41 (the electrode 40).

The forming of the third layer 33 includes forming the third layer 33 on surfaces of the sacrificial layers (the first films 61). The semiconductor layer 20 is formed after the forming of the first layer 31. The removing of the sacrificial layers is implemented after the forming of the semiconductor layer 20 (in the example, after the forming of the core pillar 20c). The forming of the first electrode 41 includes forming the first electrode 41 on surfaces of the third layers 33 exposed by the removing of the sacrificial layers. Thus, the nonvolatile semiconductor memory device 121 may be manufactured by a replacement method.

FIG. 7A and FIG. 7B are schematic cross-sectional views illustrating another nonvolatile semiconductor memory device according to the fourth embodiment.

FIG. 7B is a line A1-A2 cross-sectional view of FIG. 7A.

As shown in FIG. 7A, the semiconductor layer 20, the first electrode 41, the second electrode 42, the inter-layer insulating film 45i, the first to third layers 31 to 33, and the multiple nitride portions 35 are provided in the nonvolatile semiconductor memory device 122 according to the embodiment as well. The multiple nitride portions 35 are provided between the second layer 32 and the third layer 33. Otherwise, the nonvolatile semiconductor memory device 122 is similar to the nonvolatile semiconductor memory device 121.

In the nonvolatile semiconductor memory device 122, the semiconductor layer 20 extends along the second direction (the Z-axis direction) through the stacked body SB. Otherwise, the nonvolatile semiconductor memory device 122 is similar to the nonvolatile semiconductor memory device 112. In the nonvolatile semiconductor memory device 122 as well, for example, stable operations are obtained even if the size of the memory cell is reduced. As a result, for example, the bit density can be increased.

An example of a method for manufacturing the nonvolatile semiconductor memory device 122 will now be described.

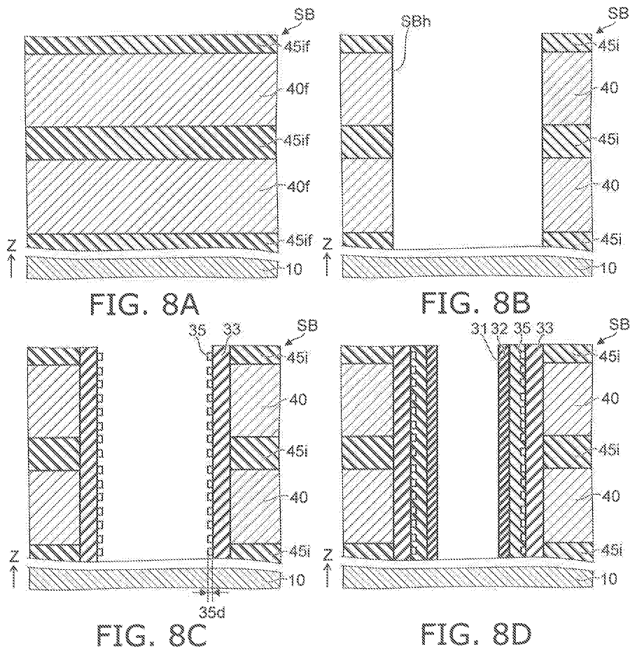

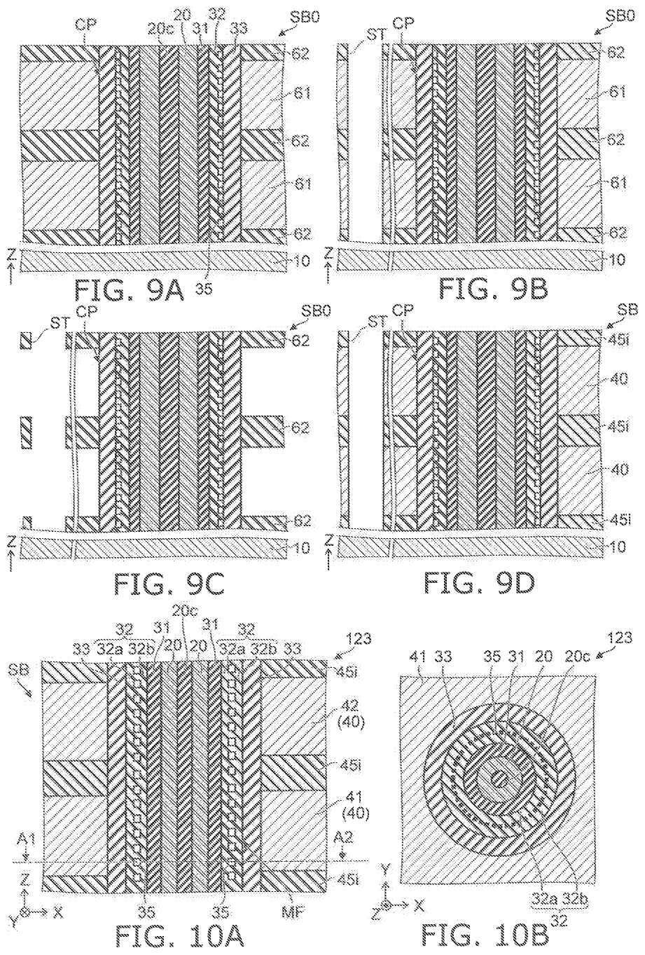

FIG. 8A to FIG. 8D are schematic cross-sectional views in order of the processes, illustrating the method for manufacturing the other nonvolatile semiconductor memory device according to the fourth embodiment.

As shown in FIG. 8A and FIG. 8B, the stacked body SB is formed by alternately stacking the conductive layer 40f used to form the electrode 40 and the insulating layer 45if used to form the inter-layer insulating film 45i on the base body 10 and by further forming the hole SBh in the stacked body SB.

As shown in FIG. 8C, the third layer 33 is formed on the side wall of the hole SBh; and the multiple nitride portions 35 are formed on the third layer 33. The processing described in reference to FIG. 5C is performed to form the multiple nitride portions 35.

As shown in FIG. 8D, the second layer 32 is formed on a portion of the surface of the third layer 33 and on the multiple nitride portions 35; and the first layer 31 is formed on the surface of the second layer 32.

The nonvolatile semiconductor memory device 122 can be formed by forming the semiconductor layer 20 on the surface of the first layer 31 and by further forming the core pillar 20c by filling an insulating material into the remaining space.

In the example, the forming of the multiple nitride portions 35 is implemented after the forming of the third layer 33. The forming of the second layer 32 is implemented after the forming of the multiple nitride portions 35. The forming of the first layer 31 is implemented after the forming of the second layer 32.

FIG. 9A to FIG. 9D are schematic cross-sectional views in order of the processes, illustrating another method for manufacturing the nonvolatile semiconductor memory device according to the fourth embodiment.

As shown in FIG. 9A, the stacked body SB0 is formed on the base body 10; and the pillar unit PP is formed in the stacked body SB0. In the pillar unit PP, the multiple nitride portions 35 are provided between the third layer 33 and the second layer 32.

As shown in FIG. 9B to FIG. 9D, the slit ST (that may be a hole) is formed in the stacked body SB0; the first films 61 are removed via the slit ST; and the electrodes 40 are formed by filling a conductive material into the space formed where the first films 61 were removed. The remaining second films 62 become the inter-layer insulating films 45i. Thereby, the nonvolatile semiconductor memory device 122 is formed.

FIG. 10A and FIG. 10B are schematic cross-sectional views illustrating another nonvolatile semiconductor memory device according to the fourth embodiment.

FIG. 10B is a line A1-A2 cross-sectional view of FIG. 0A.

As shown in FIG. 10A, the semiconductor layer 20, the first electrode 41, the second electrode 42, the inter-layer insulating film 45i, the first to third layers 31 to 33, and the multiple nitride portions 35 are provided in the nonvolatile semiconductor memory device 123 according to the embodiment as well. The multiple nitride portions 35 are provided between the first region 32a and the second region 32b of the second layer 32. Otherwise, the nonvolatile semiconductor memory device 123 is similar to the nonvolatile semiconductor memory device 121.

In the nonvolatile semiconductor memory device 123, the semiconductor layer 20 extends along the second direction (the Z-axis direction) through the stacked body SB. Otherwise, the nonvolatile semiconductor memory device 123 is similar to the nonvolatile semiconductor memory device 113. In the nonvolatile semiconductor memory device 123 as well, for example, stable operations are obtained even if the size of the memory cell is reduced. As a result, for example, the bit density can be increased.

An example of a method for manufacturing the nonvolatile semiconductor memory device 123 will now be described.

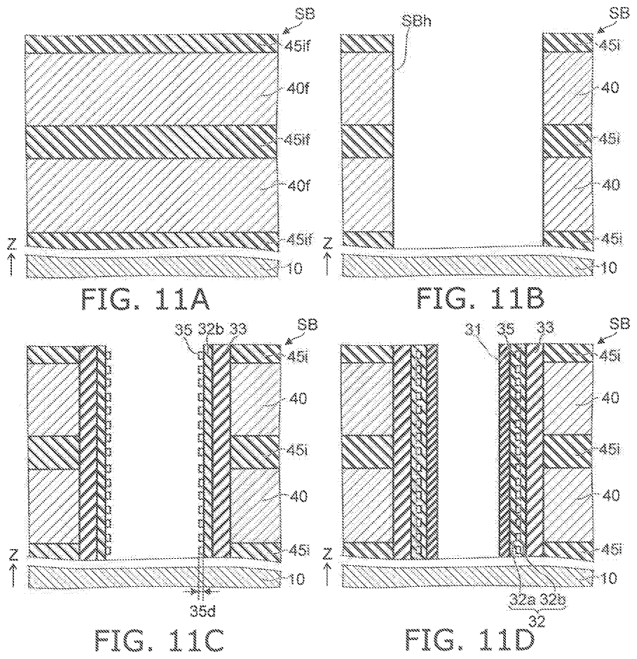

FIG. 11A to FIG. 11D are schematic cross-sectional views in order of the processes, illustrating the method for manufacturing the other nonvolatile semiconductor memory device according to the fourth embodiment.

As shown in FIG. 11A and FIG. 11B, the stacked body SB is formed by alternately stacking the conductive layer 40f used to form the electrode 40 and the insulating layer 45if used to form the inter-layer insulating film 45i on the base body 10; and the hole SBh is further formed in the stacked body SB.

As shown in FIG. 11C, the third layer 33 is formed on the side wall of the hole SBh; and a portion (the second region 32b) of the second layer 32 is formed on the third layer 33. The multiple nitride portions 35 are formed on the surface of the portion of the second layer 32. The processing described in reference to FIG. 5C is performed to form the multiple nitride portions 35.

As shown in FIG. 11D, another portion (the first region 32a) of the second layer 32 is formed on a portion of the surface of the second region 32b and on the multiple nitride portions 35; and the first layer 31 is formed on the surface of the first region 32a.

The nonvolatile semiconductor memory device 123 can be formed by forming the semiconductor layer 20 on the surface of the first layer 31 and by forming the core pillar 20c by filling an insulating material into the remaining space.

In the example, one portion (the second region 32b) of the second layer 32 is formed after the forming of the third layer 33; and the forming of the multiple nitride portions 35 is implemented after the forming of the one portion (the second region 32b) of the second layer 32. One other portion (the first region 32a) of the second layer 32 is formed after the forming of the multiple nitride portions 35. The forming of the first layer 31 is implemented after the forming of the one other portion (the first region 32a) of the second layer 32 recited above.

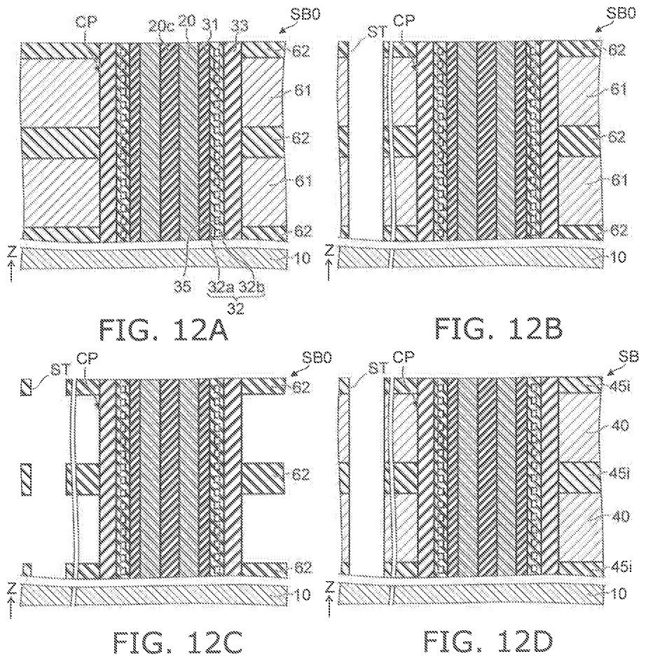

FIG. 12A to FIG. 12D are schematic cross-sectional views in order of the processes, illustrating another method for manufacturing the nonvolatile semiconductor memory device according to the fourth embodiment.

As shown in FIG. 12A, the stacked body SB0 is formed on the base body 10; and the pillar unit PP is formed in the stacked body SB0. In the pillar unit PP, the multiple nitride portions 35 are provided between the first region 32a and the second region 32b of the second layer 32.

As shown in FIG. 12B to FIG. 12D, the slit ST (that may be a hole) is formed in the stacked body SB0; the first films 61 are removed via the slit ST; and the electrodes 40 are formed by filling a conductive material into the space formed where the first films 61 were removed. The remaining second films 62 become the inter-layer insulating films 45L. Thereby, the nonvolatile semiconductor memory device 123 is formed.

In the manufacturing methods described in reference to FIG. 5A to FIG. 5D, FIG. 5A to FIG. 5D, and FIG. 11A to FIG. 11D, the stacked body SB is formed prior to the forming of the third layer 33. In other words, the first electrode 41 is formed prior to the forming of the third layer 33. Then, the semiconductor layer 20 is formed after the forming of the first layer 31.

Conversely, in the manufacturing methods described in reference to FIG. 6A to FIG. 6D, FIG. 9A to FIG. 9D, and FIG. 12A to FIG. 12D, the electrodes 40 (the first electrode 41, the second electrode 42, etc.) are formed after forming the first to third layers 31 to 33, the multiple nitride portions 35, and the semiconductor layer 20.

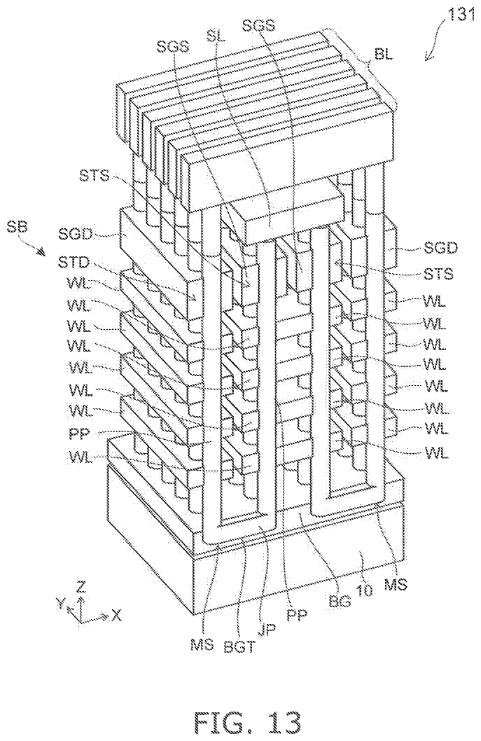

FIG. 13 is a schematic perspective view illustrating the nonvolatile semiconductor memory device according to the fourth embodiment.

In FIG. 13, at least some of the insulating portions are not illustrated for easier viewing of the drawing.

The nonvolatile semiconductor memory device 131 shown in FIG. 13 has the configuration of the nonvolatile semiconductor memory devices 121 to 131 recited above. The memory cells are arranged three-dimensionally in the nonvolatile semiconductor memory device 131.

In the nonvolatile semiconductor memory device 131, a back gate BG is provided on the base body 10. The stacked body SB is provided on the back gate BG. The stacked body SB includes multiple conductive layers WL and the multiple insulating layers (not-illustrated, corresponding to, for example, the inter-layer insulating films 45i) that are provided alternately. The stacking direction of the stacked body SB corresponds to the Z-axis direction.

The base body 10 is, for example, a semiconductor substrate (a silicon substrate, etc.). The back gate BG includes, for example, silicon including an impurity. The conductive layer WL includes, for example, a metal (e.g., tungsten, etc.) or a semiconductor (e.g., silicon including an impurity, etc.). For example, the conductive layer WL is used as a word line.

The nonvolatile semiconductor memory device 131 includes multiple memory strings MS. One memory string MS includes the pillar unit PP. In the example, one memory string MS includes two pillar units PP and a linking unit JP. The linking unit JP links the lower ends of the two pillar units PP. For example, the memory string MS has a U-shaped configuration.

For example, the pillar unit PP has a columnar configuration (a circular columnar configuration, a flattened circular columnar configuration, etc.). The pillar unit PP extends in the Z-axis direction through the stacked body SB. A drain-side selection gate SGD is provided at one upper end portion of the pillar unit PP. A source-side selection gate SGS is provided at one other upper end portion of the pillar unit PP. For example, the drain-side selection gate SGD and the source-side selection gate SGS are used as upper selection gates. For example, the drain-side selection gate SOD and the source-side selection gate SGS are provided, with an insulating layer interposed, on the conductive layer WL of the uppermost layer. The drain-side selection gate SGD and the source-side selection gate SGS include, for example, silicon including an impurity. An insulating separation film (not illustrated) is provided between the drain-side selection gate SGD and the source-side selection gate SGS. These gates extend along the Y-axis direction.

The stacked body SB that is under the drain-side selection gate SGD and the stacked body SB that is under the source-side selection gate SGS also are separated by an insulating separation film. The stacked body SB extends in the Y-axis direction.

A source line SL (e.g., a metal film) is provided on the source-side selection gate SOS with an insulating layer interposed. Multiple bit lines BL (e.g., metal films) are provided, with an insulating layer interposed, on the drain-side selection gate SGD and on the source line SL. Each of the multiple bit lines BL extends in the X-axis direction.

The multiple conductive layers WL correspond to the multiple electrodes 40. The multiple conductive layers WL correspond respectively to the multiple memory cells.

A drain-side selection transistor STD is provided at one upper end portion of the pillar unit PP. A source-side selection transistor STS is provided at one other upper end portion of the pillar unit PP. The memory cells, the drain-side selection transistor STD, and the source-side selection transistor STS are vertical transistors. A current flows along the Z-axis direction in these transistors.

The drain-side selection gate SGD functions as a gate electrode (a control gate) of the drain-side selection transistor STD. An insulating film (not illustrated) is provided between the drain-side selection gate SGD and the semiconductor layer 20. The insulating film functions as a gate insulating film of the drain-side selection transistor STD. The channel body (the semiconductor layer 20) of the drain-side selection transistor STD is connected to the bit line BL above the drain-side selection gate SGD.

The source-side selection gate SGS functions as a gate electrode (a control gate) of the source-side selection transistor STS. An insulating film (not illustrated) is provided between the source-side selection gate SGS and the semiconductor layer 20. The insulating film functions as a gate insulating film of the source-side selection transistor STS. The channel body (the semiconductor layer 20) of the source-side selection transistor STS is connected to the source line SL above the source-side selection gate SGS.

A back gate transistor BGT is provided at the linking unit JP of the memory string MS. The back gate BG functions as a gate electrode (a control gate) of the back gate transistor BGT.

The memory film MF that is provided in the pillar unit PP may be provided also inside the back gate BG. The memory film MF functions as a gate insulating film of the back gate transistor BGT.

The multiple memory cells are provided between the drain-side selection transistor STD and the back gate transistor BGT. The multiple memory cells are provided also between the back gate transistor BGT and the source-side selection transistor STS. The multiple conductive layers WL are used respectively as the control gates of the multiple memory cells.

The multiple memory cells, the drain-side selection transistor STD, the back gate transistor BGT, and the source-side selection transistor STS are connected in series via the semiconductor layer 20. Thereby, one memory string MS that has a U-shaped configuration is formed. The multiple memory strings MS are arranged in the X-axis direction and the Y-axis direction. The multiple memory cells are provided three-dimensionally in the X-axis direction, the Y-axis direction, and the Z-axis direction.

In the embodiment, the two pillar units PP may not be linked. For example, the lower end portion of one pillar unit PP may be connected to the source line SL; and, for example, the upper end portion of the one pillar unit PP may be connected to the bit line BL.

### Fifth Embodiment

In a fifth embodiment, the semiconductor layer 20 has a substrate configuration.

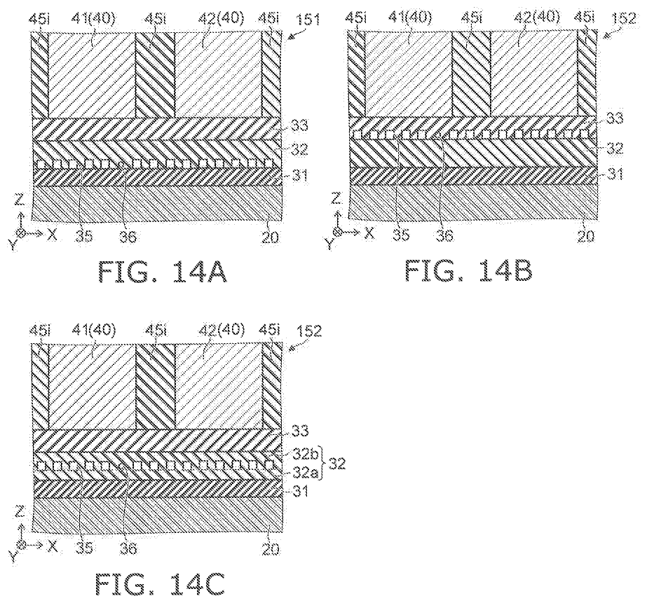

FIG. 14A to FIG. 14C are schematic cross-sectional views illustrating nonvolatile semiconductor memory devices according to the fourth embodiment.

As shown in FIG. 14A to FIG. 14C, the nonvolatile semiconductor memory devices 151 to 153 according to the embodiment include the semiconductor layer 20, the first electrode 41, the first layer 31, the second layer 32, the third layer 33, and the multiple nitride portions 35.

For example, a semiconductor substrate (e.g., a silicon substrate or the like) is used as the semiconductor layer 20. For example, the semiconductor layer 20 may have an SOI structure. Otherwise, the nonvolatile semiconductor memory devices 151 to 153 are similar to the nonvolatile semiconductor memory devices 111 to 113.

For example, the nonvolatile semiconductor memory devices 151 to 153 are manufactured as follows.

The first layer 31 is formed on the semiconductor layer 20. The second layer 32 is formed after the forming of the first layer 31. The third layer 33 is formed after the forming of the second layer 32. The first electrode 41 (and the second electrode 42, etc.) are formed after the forming of the third layer 33.

The forming of the multiple nitride portions 35 is implemented between the forming of the first layer 31 and the forming of the third layer 33.

For example, the forming of the multiple nitride portions 35 is performed between the forming of the first layer 31 and the forming of the second layer 32. Thereby, the nonvolatile semiconductor memory device 151 is formed. For example, the forming of the multiple nitride portions 35 is performed between the forming of the second layer 32 and the forming of the third layer 33. Thereby, the nonvolatile semiconductor memory device 152 is formed. For example, the forming of the multiple nitride portions 35 is performed between the forming of a portion (the first region 32a) of the second layer 32 and the forming of another portion (the second region 32b) of the second layer 32. Thereby, the nonvolatile semiconductor memory device 153 is formed.

For example, three-dimensional memory is being developed as flash memory of a nonvolatile semiconductor memory device. For example, MONOS memory cells are provided in the three-dimensional memory. In the MONOS memory cell, the charge is stored in discrete defects inside the charge storage layer. If the density of the defects is high, much charge can be stored; and the range of the possible threshold voltages is enlarged. On the other hand, if the density of the defects is high and the distance between the defects is short, the charge moves easily between the defects; and the data retention characteristics degrade. The thickness of the charge storage layer is reduced as the memory cells are downscaled. As the thickness of the charge storage layer becomes thin, the stored charge amount decreases. Therefore, the tolerance range of the programming voltage and the erasing voltage decreases.

In the embodiments, the multiple nitride portions 35 of the nitride molecules 35M are provided in the memory film MF. The multiple nitride portions 35 are disposed discretely. The length 35d (the size) of the multiple nitride portions 35 is not more than the maximum value 35L of the size of the nitride molecule 35M. Thereby, the stored amount of the charge is increased. The stored charge is not de-trapped easily. Thereby, the tolerance range of the programming voltage and the erasing voltage is enlarged. Good data retention characteristics are obtained. Thereby, appropriate operations are performed even if the size of the memory cell is reduced.

According to the embodiments, a nonvolatile semiconductor memory device and a method for manufacturing the nonvolatile semiconductor memory device can be provided in which the bit density can be increased.

In this specification, “perpendicular” and “parallel” include not only strictly perpendicular and strictly parallel but also, for example, the fluctuation due to manufacturing processes, etc.; and it is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as semiconductor layers, electrodes, the first to third layers, and nitride portions, etc., included in nonvolatile semiconductor memory devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nonvolatile semiconductor memory devices and all methods for manufacturing the nonvolatile semiconductor memory device practicable by an appropriate design modification by one skilled in the art based on the nonvolatile semiconductor memory devices and the methods for manufacturing the nonvolatile semiconductor memory device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1-17. (canceled)

18. A nonvolatile semiconductor memory device, comprising:
a semiconductor layer;
a first electrode;
a first layer provided between the semiconductor layer and the first electrode;
a second layer provided between the first layer and the first electrode, a second energy of a conduction band edge of the second layer being lower than a first energy of a conduction band edge of the first layer, the second layer including a first region and a second region, the first region being provided between the first layer and the second region;
a third layer provided between the second layer and the first electrode, a third energy of a conduction band edge of the third layer being higher than the second energy;
a plurality of nitride portions of nitride molecules, the plurality of nitride portions being provided between the first layer and the second layer, or between the second layer and the third layer;
a second electrode arranged with the first electrode in a second direction, the second direction crossing a first direction, the first direction being from the semiconductor layer toward the first electrode; and
an insulating film provided between the first electrode and the second electrode,
the first layer being a tunneling insulating layer,
the second layer being a charge storage layer,
the third layer being a blocking insulating layer,
the nitride molecule including at least one of TiN, ZrN, HfN, VN, NbN, TaN, CrN, MoN, WN, BN, AlN, GaN, or InN,
a length in the first direction of the plurality of nitride portions being not more than a maximum value of a size of the nitride molecule,
the first layer being further provided between the second electrode and the semiconductor layer,
the second layer being further provided between the second electrode and the first layer,
the first layer and the second layer being provided between the insulating film and the semiconductor layer, and
at least one of the nitride portions being further provided between the insulating film and the semiconductor layer.

19. The device according to claim 18, wherein a density of the plurality of nitride portions in a surface perpendicular to the first direction is not less than 1×10¹³ cm⁻² and not more than 1×10¹⁵ cm⁻².

20. The device according to claim 18, wherein the plurality of nitride portions are arranged along a first surface of the semiconductor layer opposing the first layer.

21. The device according to claim 18, wherein the plurality of nitride portions are arranged along a second surface of the first electrode opposing the third layer.

22. The device according to claim 18, the third layer being further provided between the second electrode and the second layer.

23. The device according to claim 22, wherein the semiconductor layer extends along the second direction through a stacked body, the stacked body including the first electrode, the insulating film, and the second electrode.

24. A nonvolatile semiconductor memory device, comprising:
a semiconductor layer;
a first electrode;
a first layer provided between the semiconductor layer and the first electrode;
a second layer provided between the first layer and the first electrode, a second energy of a conduction band edge of the second layer being lower than a first energy of a conduction band edge of the first layer, the second layer including a first region and a second region, the first region being provided between the first layer and the second region;
a third layer provided between the second layer and the first electrode, a third energy of a conduction band edge of the third layer being higher than the second energy; and
a plurality of nitride portions of nitride molecules, the plurality of nitride portions being provided between the first layer and the second layer, or between the second layer and the third layer;
a second electrode arranged with the first electrode in a second direction, the second direction crossing a first direction, the first direction being from the semiconductor layer toward the first electrode; and
an insulating film provided between the first electrode and the second electrode,
the nitride molecule including nitrogen and a first element of one of Group 4, Group 5, Group 6, or Group 13,
a density of the plurality of nitride portions in a surface crossing the first direction being not less than 1×10¹³ cm⁻² and not more than 1×10¹⁵ cm⁻²,
the first layer being further provided between the second electrode and the semiconductor layer,
the second layer being further provided between the second electrode and the first layer,
the first layer and the second layer being provided between the insulating film and the semiconductor layer, and
at least one of the nitride portions being further provided between the insulating film and the semiconductor layer.

25. The device according to claim 20, further comprising a particle of the first element provided at the one of between the first region and the second region, between the first layer and the second layer, or between the second layer and the third layer.

26. A method for manufacturing a nonvolatile semiconductor memory device, the device including a semiconductor layer, a first electrode, a second electrode, an insulating film, a first layer, a second layer, and a third layer, the first layer being provided between the semiconductor layer and the first electrode, the second layer being provided between the first layer and the first electrode, a second energy of a conduction band edge of the second layer being lower than a first energy of a conduction band edge of the first layer, the third layer being provided between the second layer and the first electrode, a third energy of a conduction band edge of the third layer being higher than the second energy, the second electrode being arranged with the first electrode in a second direction, the second direction crossing a first direction, the first direction being from the semiconductor layer toward the first electrode, the insulating film being provided between the first electrode and the second electrode, the first layer being further provided between the second electrode and the semiconductor layer, the second layer being further provided between the second electrode and the first layer, the first layer and the second layer being provided between the insulating film and the semiconductor layer, the method comprising:
forming a plurality of nitride portions of nitride molecules between the first layer and the second layer, or between the second layer and the third layer,
the nitride molecule including nitrogen and a first element of one of Group 4, Group 5, Group 6, or Group 13,
a length in the first direction of the plurality of nitride portions being not more than a maximum value of a size of the nitride molecule, and
at least one of the nitride portions being further provided between the insulating film and the semiconductor layer.

27. The method according to claim 26, wherein a density of the plurality of nitride portions in a surface crossing the first direction is not less than 1×10¹³ cm⁻² and not more than 1×10¹⁵ cm⁻².
